(19) United States
(12) Patent Application Publication
(10) Pub. No.: US 2017/0341113 A1
(43) Pub. Date: Nov. 30, 2017

(54) APPARATUS AND METHOD FOR TREATING A SUBSTRATE

(71) Applicant: SEMES CO., LTD., Chungcheongnam-do (KR)

(72) Inventors: DAE MIN KIM, Chungcheongnam-do (KR); YOUNG HUN LEE, Chungcheongnam-do (KR)

(21) Appl. No.: 15/604,023

(22) Filed: May 24, 2017

(30) Foreign Application Priority Data
May 26, 2016 (KR) 10-2016-0064793

(51) Int. Cl. B08B 7/04; B08B 3/08; B08B 7/00; H01L 21/02

(52) U.S. Cl. CPC B08B 7/04; H01L 21/02068; H01L 21/0206; B08B 3/08; B08B 7/0021; B08B 7/0071

(57) ABSTRACT

Provided is a method for treating a substrate which removes particle within a concave portion on a substrate having a thin film on which a pattern having the concave portion on its upper surface is formed. The substrate treating method according the present invention comprises a penetration step for penetrating a treatment liquid containing supercritical organic chemical solution into the concave portion; and a heating step for heating the substrate after the penetration step.

### CROSS-REFERENCE TO RELATED APPLICATIONS

A claim for priority under 35 U.S.C. §119 is made to Korean Patent Application No. 10-2016-0064793 filed on May 26, 2016 in the Korean Intellectual Property Office, the entire contents of which are hereby incorporated by reference.

### BACKGROUND OF THE INVENTION

This disclosure relates to an apparatus and method for treating a substrate.

Recently, as the surface structure of semiconductor devices such as semiconductor wafers, photomasks, and LCDs has become highly integrated, the patterns used in these devices have been further refined. In order to form such a pattern, an etching process is essentially required, and a cleaning process for removing residual contaminants is also required.

FIG. 1 is a cross-sectional view illustrating where a general organic chemical solution is supplied to a substrate on which a pattern having a high aspect ratio (HAR) is formed. Referring to FIG. 1, when the substrate 2, on which a pattern having a concave portion 1 with a high aspect ratio is formed, is provided as the object to be cleaned, generally a cleaning is performed using the organic chemical solution 3. At this time, when the general organic chemical solution 3 is used as the cleaning solution, the organic chemical solution 3 cannot completely penetrate into the concave portion 1 by the surface tension of the organic chemical solution 3 and the pressure of the gas staying in the concave portion 1, thereby foreign substances in the concave portion 1 cannot be removed.

### SUMMARY OF THE INVENTION

An embodiment provides a substrate treating apparatus and method therein which may clean foreign substances in the concave portion of a substrate having a high aspect ratio pattern formed on its upper surface.

The objects of the inventive concept are not limited to the above descriptions. Other objects thereof will be understandable by those skilled in the art from the following descriptions.

Embodiments of the inventive concept provide a method for treating a substrate which removes particle within a concave portion on a substrate having a thin film on which a pattern having the concave portion on its upper surface is formed. The method for treating a substrate comprises a penetration step for penetrating a treatment liquid containing supercritical organic chemical solution into the concave portion and a heating step for heating the substrate after the penetration step.

The penetration step may be performed in a high pressure chamber, and the heating step may be performed in a vacuum bake chamber.

The pattern may include a titanium nitride (TiN) capacitor having the concave portion.

The organic chemical solution may be isopropyl alcohol (IPA).

In the heating step, the substrate is heated to 200° C. or higher.

Also, embodiments of the inventive concept provide a substrate treating apparatus which removes particle within a concave portion on a substrate having a thin film on which a pattern having the concave portion on its upper surface is formed. The substrate treating apparatus comprises a high pressure chamber in which a penetrating process is performed for penetrating a treatment liquid containing an organic chemical liquid in a supercritical state into the concave portion, a vacuum bake chamber in which a process for heating the substrate is performed, and a transfer unit for transferring a substrate between the high pressure chamber and the vacuum bake chamber.

The substrate treating apparatus further comprises a controller for controlling the high pressure chamber, the vacuum bake chamber, and the transfer unit, wherein the controller controls the transfer unit to transfer the substrate having completed the process in the high pressure chamber from the high pressure chamber to the vacuum bake chamber.

The pattern may include a titanium nitride (TiN) capacitor having the concave portion.

The organic chemical solution may be isopropyl alcohol (IPA).

The substrate is heated to 200° C. or higher in the vacuum bake chamber.

The method and the apparatus according to the embodiment may clean foreign substances in the concave portion of a substrate having the high aspect ratio pattern.

### BRIEF DESCRIPTION OF THE DRAWINGS

FIG. 1 is a cross-sectional view illustrating where a general organic chemical solution is supplied to a substrate on which a pattern having a high aspect ratio (HAR) is formed.

FIG. 2 is a plan view schematically showing a substrate treating apparatus according to an embodiment of the present invention.

FIG. 3 is a perspective view showing an example of a substrate on which a high aspect ratio pattern is formed.

FIG. 4 is a cross sectional view showing the high-pressure chamber of FIG. 2.

FIG. 5 is a cross sectional view showing the vacuum bake chamber of FIG. 2.

FIG. 6 is a flowchart illustrating a substrate treating method according to an embodiment of the present invention.

FIG. 7 is a cross sectional view illustrating a state of a substrate before a substrate treating method according to an embodiment of the present invention is performed.

FIGS. 8 to 10 are illustrating a state of a substrate in each step of a substrate treating method according to an embodiment of the present invention.

FIG. 11 is a cross sectional view showing another example of a substrate on which a high aspect ratio pattern is formed.

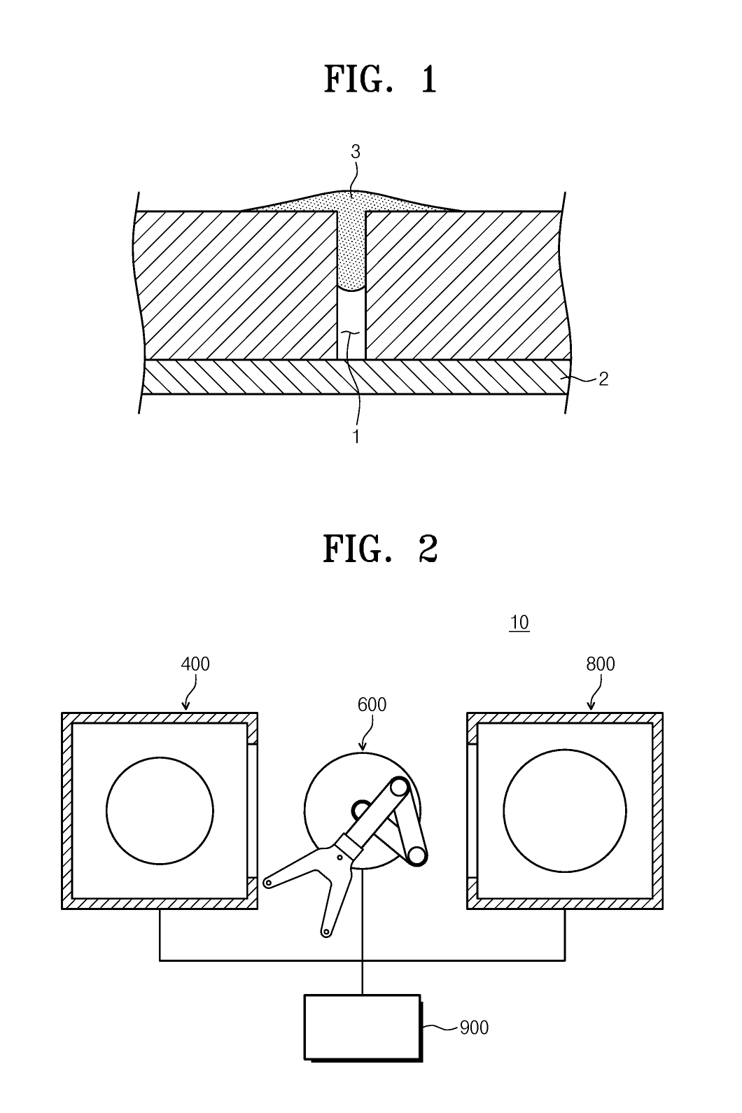

### DETAILED DESCRIPTION

Various example embodiments will be described more fully hereinafter with reference to the accompanying drawings, in which some example embodiments are shown. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Therefore, features of the drawings are exaggerated to emphasize definite explanation.

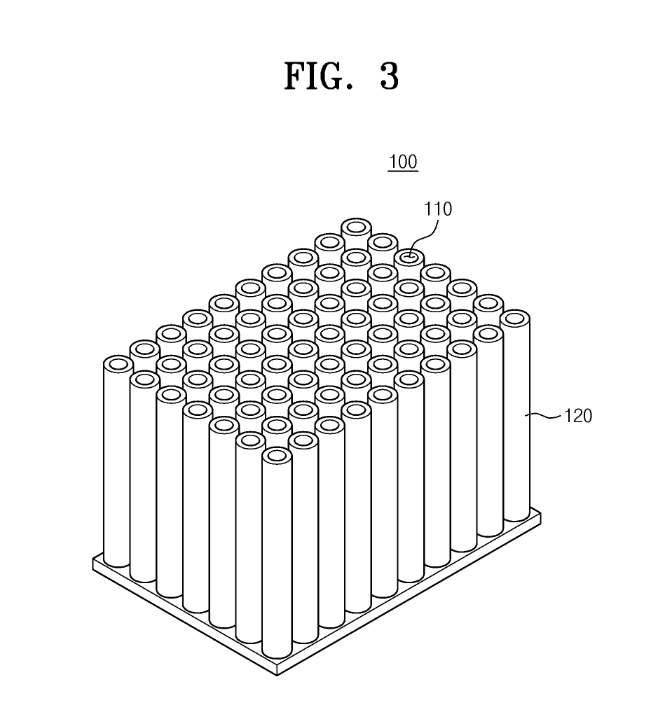

FIG. 2 is a plan view schematically showing a substrate treating apparatus 10 according to an embodiment of the present invention. FIG. 3 is a perspective view showing an example of a substrate 100 on which a high aspect ratio pattern is formed. Referring to FIGS. 2 and 3, the substrate treating apparatus 10 supplies the treatment liquid to clean the substrate 100. The substrate 100 may be provided as a substrate 100 having a thin film having a high aspect ratio pattern formed thereon. According to an embodiment, the pattern formed on the substrate 100 may include a titanium nitride (TiN) capacitor 120 having a concave portion 110. The TiN capacitor 120 extends in the upward direction from the upper surface of the substrate 100 and has a cylindrical shape whose longitudinal direction is a vertical direction. A plurality of TiN capacitors 120 are provided on the substrate 100.

When a substrate 100 having a thin film where a high aspect ratio pattern having a concave portion 110 on its top surface is formed is provided as an object to be cleaned in the substrate treating apparatus 10, the substrate treating apparatus 10 removes the particles 200 in the concave portion 110 by performing a cleaning process. According to an embodiment, the substrate treating apparatus 10 comprises a high pressure chamber 400, a transfer unit 600, a vacuum bake chamber 800 and a controller 900. In FIG. 2, the high pressure chamber 400, the transfer unit 600 and the vacuum bake chamber 800 are shown as being provided one by one, respectively. However, a plurality of high pressure chambers 400, a transfer unit 600, and a vacuum bake chamber 800 may be provided as necessary.

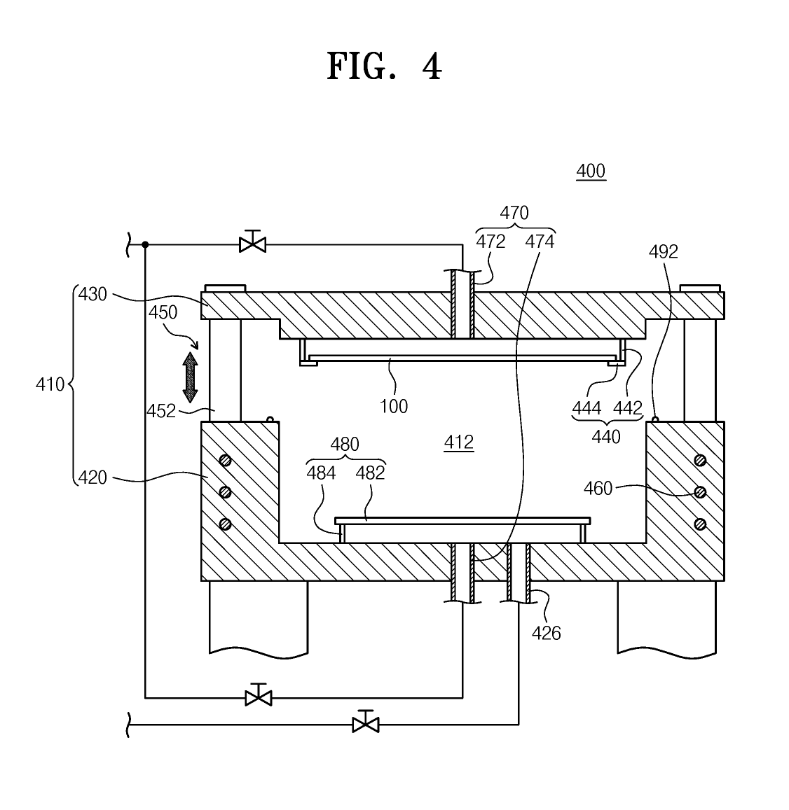

FIG. 4 is a cross sectional view showing the high pressure chamber 400 of FIG. 2. Referring to FIG. 4, in the high pressure chamber 400, a process of infiltrating the treatment liquid containing the organic chemical liquid in the supercritical state into the concave portion 110 is performed. The high pressure chamber 400 is provided with a structure for cleaning the substrate 100 using a supercritical organic chemical solution under a high pressure state. The high pressure chamber 400 comprises a housing 410, a substrate support unit 440, an elevator member 450, a heating member 460, a fluid supply unit 470, and a blocking member 480.

The housing 410 provides a treatment space 412 for treating the substrate 100. The housing 410 seals the treatment space 412 from the outside while treating the substrate 100. The housing 410 comprises a lower housing 420 and an upper housing 430. The lower housing 420 has a circular cup shape with its top opened. An exhaust port 426 is formed on the inner bottom surface of the lower housing 420. The exhaust port 426 may be formed at a position deviated from the center axis of the lower housing 420 when viewed from top. A decompression member is connected to the exhaust port 426 to exhaust particles generated in the treatment space 412. The treatment space 412 may also regulate its internal pressure through the exhaust port 426.

The upper housing 430 is combined with the lower housing 420 to form a treatment space 412 therein. The upper housing 430 is positioned above the lower housing 420. The upper housing 430 is provided with a circular plate shape. For example, the upper housing 430 may have a diameter such that its bottom faces the upper end of the lower housing 420, at a position where the central axis of the upper housing 430 and the central axis of the lower housing 420 coincide with each other. Between the upper housing 430 and the lower housing 420, a sealing member 492 sealing the treatment space 412 may be provided. Therefore, by supplying or exhausting gas through the exhaust port 426, the internal pressure can be adjusted to a high pressure state or a state close to a vacuum.

The substrate support unit 440 supports the substrate 100 in the treatment space 412. The substrate supporting unit 440 supports the substrate 100 such that the treatment surface of the substrate 100 faces upward. The substrate support unit 440 comprises a supporter 442 and a substrate supporter 444. The supporter 442 is provided in a bar shape extending downward from the bottom surface of the upper housing 430. A plurality of supports 442 is provided. For example, the number of the supporter 442 may be four. The substrate supporter 444 supports the bottom edge region of the substrate 100. A plurality of substrate supporter 444 is provided, each supporting a different area of the substrate 100. For example, the number of the substrate supporter 444 may be two. The substrate supporter 444 is provided in a rounded plate shape when viewed from top. The substrate supporter 444 is positioned inside the supporter 442 when viewed from top. Each substrate supporter 444 is provided to have a ring shape in combination with each other. Each of the substrate supporters 444 is spaced apart from each other.

The elevator member 450 adjusts the relative position between the upper housing 430 and the lower housing 420. The elevator member 450 moves one of the upper housing 430 and the lower housing 420. In the embodiment, the position of the upper housing 430 is fixed and the distance between the upper housing 430 and the lower housing 420 is adjusted by moving the lower housing 420. Alternatively, the substrate support unit 440 may be installed in the fixed lower housing 420, and the upper housing 430 may be moved. The elevator member 450 moves the lower housing 420 such that the relative position between the upper housing 430 and the lower housing 420 is moved to the open position and the closed position. The open position is a position where the upper housing 430 and the lower housing 420 are spaced from each other such that the treatment space 412 communicates with the outside. The closed position is a position where the upper housing 430 and the lower housing 420 are in contact with each other to thereby close the treatment space 412 from the outside. The elevator member 450 moves up and down the lower housing 420 to open or close the treatment space 412. The elevator member 450 includes a plurality of elevating shafts 452 connecting the upper housing 430 and the lower housing 420 to each other. The elevating shafts 452 are positioned between the upper end of the lower housing 420 and the upper housing 430. The elevating shafts 452 are to be arranged along the circumferential direction of the upper end of the lower housing 420. Each elevating shaft 452 can be fixedly coupled to the upper end of the lower housing 420 through the upper housing 430. As the elevating shafts 452 move up or down, the height of the lower housing 420 changes, and the distance between the upper housing 430 and the lower housing 420 can be adjusted.

The heating member 460 heats the treatment space 412. The heating member 460 heats the organic chemical solution in the supercritical state supplied to the treatment space 412 to a temperature above the critical temperature and maintains it in the supercritical organic chemical solution. The heating member 460 may be embedded in the wall of at least one of the upper housing 430 and the lower housing 420. For example, the heating member 460 may be provided as a heater that receives power from the outside and generates heat.

The fluid supply unit 470 supplies the treatment liquid to the treatment space 412. The treatment liquid is provided as an organic chemical liquid in a supercritical state. For example, Isopropyl alcohol (IPA) may be provided as the treatment liquid. The fluid supply unit 470 includes an upper supply port 472 and a lower supply port 474. The upper supply port 472 is formed in the upper housing 430 and the lower supply port 474 is formed in the lower housing 420. The upper supply port 472 and the lower supply port 474 are positioned facing each other in the vertical direction. The upper supply port 472 and the lower supply port 474 are positioned to coincide with the central axis of the treatment space 412. The supercritical organic chemical solution of the same kind is supplied to the upper supply port 472 and the lower supply port 474, respectively. According to an example, supercritical organic chemical solution may be supplied from a supply port opposed to the non-treated surface of the substrate 100, and then the supercritical organic chemical solution may be supplied from the supply port opposed to the treatment surface of the substrate 100. Therefore, the supercritical organic chemical solution may be supplied from the lower supply port 474, and then the supercritical organic chemical solution may be supplied from the upper supply port 472. This is to prevent the initially supplied fluid from being supplied to the substrate 100 with the critical pressure or critical temperature not yet reached.

The blocking member 480 prevents the fluid supplied from the lower supply port 474 from being directly supplied to the non-treated surface of the substrate 100. The blocking member 480 includes a blocking plate 482 and a support 484. The blocking plate 482 is positioned between the lower supply port 474 and the substrate support unit 440. The blocking plate 482 is provided to have a circular plate shape. The blocking plate 482 has a smaller diameter than the inner diameter of the lower housing 420. The blocking plate 482 has a diameter that obscures both the lower supply port 474 and the exhaust port 426 when viewed from top. For example, the blocking plate 482 may be provided to have a diameter that is greater than or equal to the diameter of the substrate 100. The support 484 supports the blocking plate 482. The support 484 is provided in a plurality and is arranged along the circumferential direction of the blocking plate 482. Each support 484 is arranged to be spaced apart from each other at regular intervals.

Again, referring to FIG. 2, the transfer unit 600 transfers the substrate 100 between the high pressure chamber 400 and the vacuum bake chamber 800. The transfer unit 600 is located between the high pressure chamber 400 and the vacuum bake chamber 800. The hand of the transfer unit 600 may be provided in various configurations and shapes capable of supporting the substrate 100. For example, the hand of the transfer unit 600 may be provided as a hand of a vacuum suction method. According to an embodiment, The hand of the transfer unit 600 is capable of linear motion in the vertical direction and the horizontal direction by the driving member, and is provided so as to be rotatable about the vertical direction.

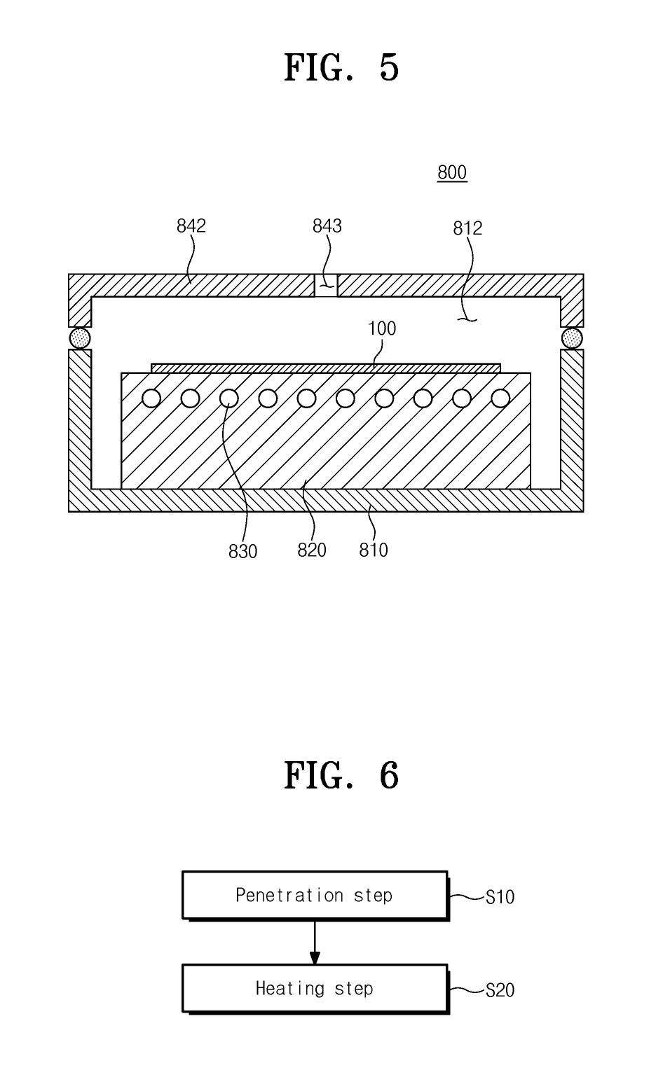

FIG. 5 is a cross sectional view showing the vacuum bake chamber 800 of FIG. 2. Referring to FIG. 5, in the vacuum bake chamber 800, a process for heating the substrate 100 is performed. In the vacuum bake chamber 800, a process for heating the substrate 100 where the process of infiltrating the supercritical organic chemical solution into the concave portion 110 in the high pressure chamber 400 is completed is performed. The vacuum bake chamber 800 is provided with a composition capable of heating the substrate 100 in a vacuum state. The vacuum bake chamber 800 includes a housing 810, a heating plate 820, a heat treatment member 830, and a cover 842.

The housing 810 provides a treatment space 812 for heating the substrate W therein. The housing 810 is provided so as to have a cylindrical shape with its top opened. The heating plate 820 is located in the treatment space 812 of the housing 810. The heating plate 820 is provided in the form of a circular plate. The upper surface of the heating plate 820 is provided as a supporting region where the substrate W is placed. On the upper surface of the heating plate 820, a plurality of pin holes is formed. The pin holes are spaced at equal intervals from each other. Each pin hole is provided with a lift pin (not shown). The lift pins (not shown) are provided to move up and down. For example, three pin holes may be provided.

The heat treatment member 830 heats the substrate W placed on the heating plate 820 to a predetermined temperature. The heat treatment member 830 includes a plurality of heaters 830. Each heater 830 is located inside the heating plate 820. Each heater 830 is positioned on the same plane. Each heater 830 heats different areas of the heating plate 820. The areas of the heating plate 820 corresponding to the respective heaters 830 are provided as the heating zones. For example, the heating zones may be fifteen. For example, the heater 830 may be a thermoelectric element or a hot wire.

The cover 842 opens and closes the treatment space 812 of the housing 810. The cover 842 may be mounted to the housing 810 to block the treatment space 812 from the outside. The cover 842 is provided to have a circular plate shape. An exhaust hole 843 is formed in the cover 842. The exhaust hole 843 is formed so as to correspond to the central axis of the body 842. The atmosphere in the treatment space 812 and the particles generated in the treatment space 812 are exhausted to the outside through the exhaust hole 843. A pressure regulator is connected to the exhaust hole 843 to suck the gas in the process space 812, thereby making the inner pressure of the treatment space 812 a pressure state close to a vacuum. The cover 842 is moved up and down by the driving member. The driving member can be provided in various configurations and shapes capable of moving the cover up and down.

Again referring to FIG. 2, the controller 900 controls the high pressure chamber 400, the vacuum bake chamber 800, and the transfer unit 600. The controller 900 controls the transfer unit 600 to transfer the processed substrate 100 in the high pressure chamber 400 from the high pressure chamber 400 to the vacuum bake chamber 800.

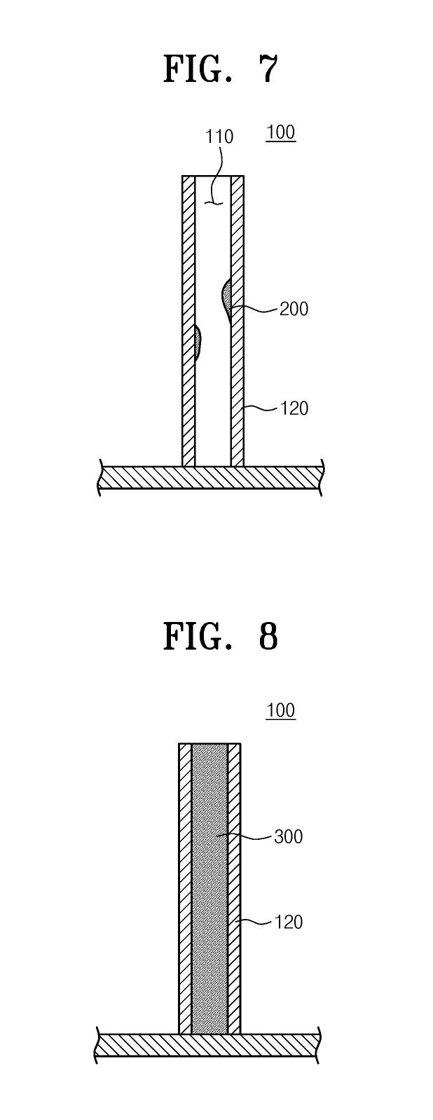

A substrate treating method according to an embodiment of the present invention will be described using the substrate treating apparatus 10 described above. FIG. 6 is a flowchart illustrating a substrate treating method according to an embodiment of the present invention. FIG. 7 is a cross sectional view illustrating a state of a substrate before a substrate treating method according to an embodiment of the present invention is performed. Referring to FIGS. 6 and 7, the substrate treating method is a method of cleaning the substrate. The substrate processing method removes the particles 200 in the concave portion 110 from the substrate 100 having a thin film having a pattern having concave portion 110 on its upper surface. The substrate processing method includes a penetration step S10 and a heating step S20.

FIGS. 8 to 10 are illustrating a state of a substrate in each step of a substrate treating method according to an embodiment of the present invention.

Referring to FIG. 8, in the penetration step S10, the treatment liquid containing the organic chemical solution in the supercritical state is infiltrated into the concave portion 110. The organic chemical solution is supplied in a supercritical state in which the surface tension is zero, the organic chemical solution does not form a film and may penetrate into the concave portion 110 without being resisted by the pressure of the gas already present in the concave portion 110. Therefore, the particles in the concave portion 110 react with the organic chemical solution to form the reactant 300. The penetration step S10 is performed in the high pressure chamber 400. For example, in the penetration step S10, the substrate 100 is placed on the substrate support unit 440, and the upper housing 430 and the lower housing 420 are moved to the closed position by the elevating member 450, so the treatment space 412 is sealed. A pressurized gas is supplied through the exhaust port 426 to maintain a pressure at which the organic chemical solution can be maintained in the supercritical state, and the heating member 460 heats the treatment space 412 to a temperature at which the organic chemical solution may be maintained in the supercritical state. When the pressure and the temperature in the treatment space 412 become predetermined value, the fluid supply unit 470 supplies the organic chemical liquid in the supercritical state to the treatment space 412.

After the penetration step S10 is completed, the transfer unit 600 transfers the substrate 100 from the high pressure chamber 400 to the vacuum bake chamber 800.

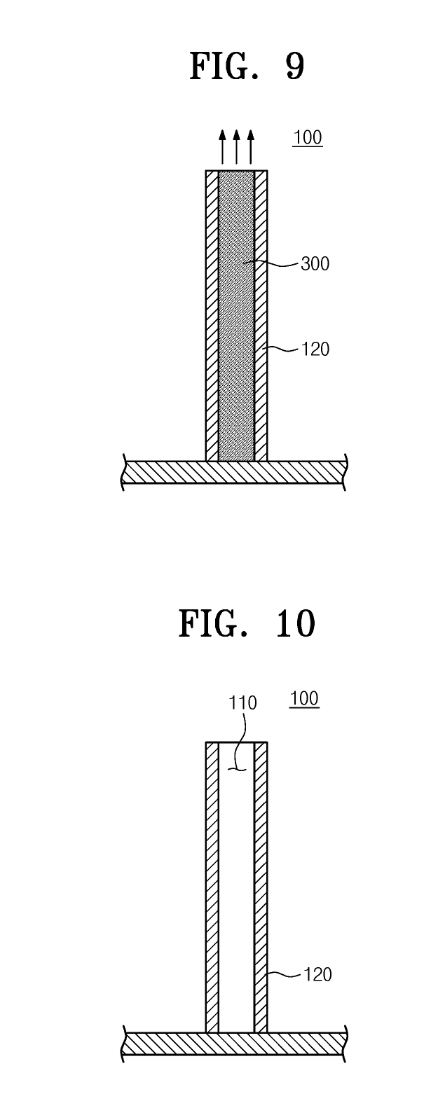

Referring to FIG. 9, in the heating step S20, the substrate 100 is heated after the penetration step S10. The heating step S20 is performed in the vacuum bake chamber 800. According to an embodiment, in the heating step S20, the substrate 100 can be heated to 200° C. or higher. By heating the substrate 100 on which the penetration step S10 is completed, the reactants 300 of the particles and the organic chemical solution are sublimated. Therefore, as shown in FIG. 10, the particles in the concave portion 110 are easily cleaned. For example, in the heating step S20, the substrate 100 is placed on the heating plate 820 with the cover 842 opened, and the cover 842 is closed. Thereafter, the processing space 812 is exhausted through the exhaust hole 843, so that the inside of the treatment space 812 is kept in a vacuum state, and the substrate 100 is heated by the heater 830.

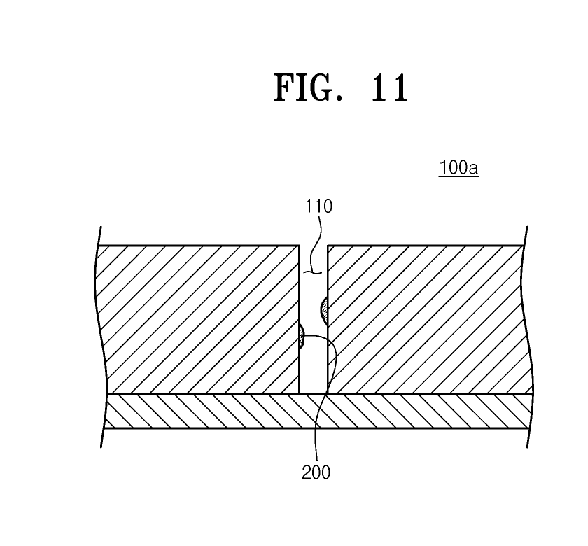

FIG. 11 is a cross sectional view showing another example of a substrate 100 on which a high aspect ratio pattern is formed. Referring to FIG. 11, unlike FIG. 3, an STI-type pattern can be provided on the substrate 100. In addition, the substrate on which the high aspect ratio pattern is formed can be provided in various shapes and structures depending on the type of the substrate.

What is claimed is:

1. A method for treating a substrate which removes particle within a concave portion on a substrate having a thin film on which a pattern having the concave portion on its upper surface is formed comprising:
a penetration step for penetrating a treatment liquid containing supercritical organic chemical solution into the concave portion; and
a heating step for heating the substrate after the penetration step.

2. The method of claim 1, wherein the penetration step is performed in a high pressure chamber.

3. The method of claim 1, wherein the heating step is performed in a vacuum bake chamber.

4. The method of claim 1, wherein the pattern includes a titanium nitride (TiN) capacitor having the concave portion.

5. The method of claim 1, wherein the organic chemical solution is isopropyl alcohol (IPA).

6. The method of claim 1, wherein the substrate is heated to 200° C. or higher in the heating step.

7. A substrate treating apparatus which removes particle within a concave portion on a substrate having a thin film formed on which a pattern having the concave portions on its upper surface is formed comprising;
a high pressure chamber in which a penetrating process is performed for penetrating a treatment liquid containing an organic chemical liquid in a supercritical state into the concave portion;
a vacuum bake chamber in which a process for heating the substrate is performed; and
a transfer unit for transferring a substrate between the high pressure chamber and the vacuum bake chamber.

8. The apparatus of claim 7, further comprises a controller for controlling the high pressure chamber, the vacuum bake chamber, and the transfer unit
wherein the controller controls the transfer unit to transfer the substrate having completed the process in the high pressure chamber from the high pressure chamber to the vacuum bake chamber.

9. The apparatus of claim 7, wherein the pattern includes a titanium nitride (TiN) capacitor having the concave portion.

10. The apparatus of claim 7, wherein the organic chemical solution is isopropyl alcohol (IPA).

11. The apparatus of claim 7, wherein the substrate is heated to 200° C. or higher in the vacuum bake chamber.
